(19) United States
(12) Patent Application Publication
(10) Pub. No.: US 2011/0279971 A1
(43) Pub. Date: Nov. 17, 2011

(54) PORTABLE COMPUTER

(75) Inventors: CHIN-HSIEN CHEN, Tu-Cheng (TW); RUNG-AN CHEN, Tu-Cheng (TW)

(73) Assignee: FOXCONN TECHNOLOGY CO., LTD., Tu-Cheng (TW)

(21) Appl. No.: 12/820,084

(22) Filed: Jun. 21, 2010

(30) Foreign Application Priority Data
May 13, 2010 (TW) 99115239

(51) Int. Cl. H05K 7/00

(52) U.S. Cl. 361/679.55

(57) ABSTRACT

An exemplary portable computer includes a casing and temperature control unit received in the casing. The casing includes a first outer portion and a second outer portion having different surface temperatures. The temperature control unit includes a controller, two temperature sensing wires and a heater. The heater is located at the first outer portion and coupled to the controller. The temperature sensing wires each includes a first end and a second end. The first ends are coupled to the controller, and the second ends respectively attaches the first and second outer portions for detecting the surface temperatures thereof. During operation, the controller reads the surface temperatures of the first and second outer portions via the temperature sensing wires, respectively, and outputs a control signal to the heater, thereby controlling operation of the heater to reduce a temperature difference between the first and second outer portions.

### BACKGROUND

1. Technical Field

The present disclosure relates to a portable electronic device, and more particularly to a portable computer having one or more small temperature difference between a plurality of different surface areas.

2. Description of Related Art

A commonly used portable computer includes a host computer and a display pivotedly connected to one side of the host computer. The host computer includes a casing with printed circuit board, electronic components, hard disk drive, FDD, CD/DVD drive and etc received therein. The casing includes a keyboard located at a rear portion that is adjacent to the display and a touch screen located at a front portion that is farthest away from the display. Left and right palm rests, with which a user's hand can directly contact, are provided in the front portion of the casing and at two opposite sides of the touch screen, respectively.

In a general layout of the portable computer, some higher-power electronic components are unavoidably arranged under the right palm rest, and some lower-power electronic components are arranged under the left palm rest. When the portable computer is used, a surface temperature at the right palm rest becomes much higher than that of the left palm rest, which resulted in a substantial temperature difference between the left and right palm rests to cause discomfort to the user.

It is thus desirable to provide a portable computer which can overcome the described limitations.

### BRIEF DESCRIPTION OF THE DRAWINGS

FIG. 1 is a schematic, assembled view of a portable computer according to a first embodiment of the present disclosure.

FIG. 2 is an exploded isometric view of a host computer of the portable computer of FIG. 1.

FIG. 3 is an exploded isometric view of a host computer according to a second embodiment.

### DETAILED DESCRIPTION

Reference will now be made to the drawing figures to describe embodiments of the present portable computer in detail.

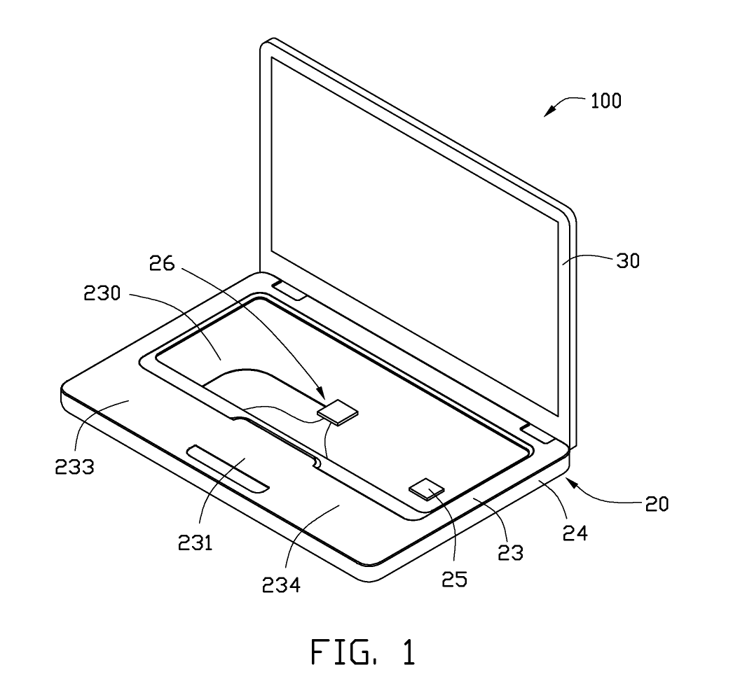

FIG. 1 shows a portable computer 100 according to a first embodiment. The portable computer 100 includes a host computer 20 and a display 30 connected to a rear edge of the host computer 20. The display 30 is pivotally attached to the host computer 20 by one or more hinges, so that the display 30 can be opened or closed relative to the host computer 20.

The host computer 20 includes a casing 22, and an electronic component 25 and a temperature control unit 26 which are received in the casing 22. The casing 22 includes a top wall 23, a bottom wall 21 spaced from the top wall 23 and a sidewall 24 extending upwardly from a periphery of the bottom wall 21 to connect the top wall 23. The top wall 23, the bottom wall 21 and the sidewall 24 cooperatively define a receiving space 28 for receiving the electronic component 25 and the temperature control unit 26 therein. The top wall 23 includes a rear portion that is adjacent to the hinge and a front portion that is farthest away from the hinge. The rear portion of the top wall 23 defines a rectangular opening 230 for receiving a keyboard (not shown) therein. A touch screen 231 is located at a middle of the front portion of the top wall 23. A left palm rest 233 or a first outer surface or a surface area, and a right palm rest 234 or a second outer surface, for supporting the hands of a user operating the keyboard, are located at left and right sides of the touch screen 231, respectively. The electronic component 25 is located adjacent to the right palm rest 234.

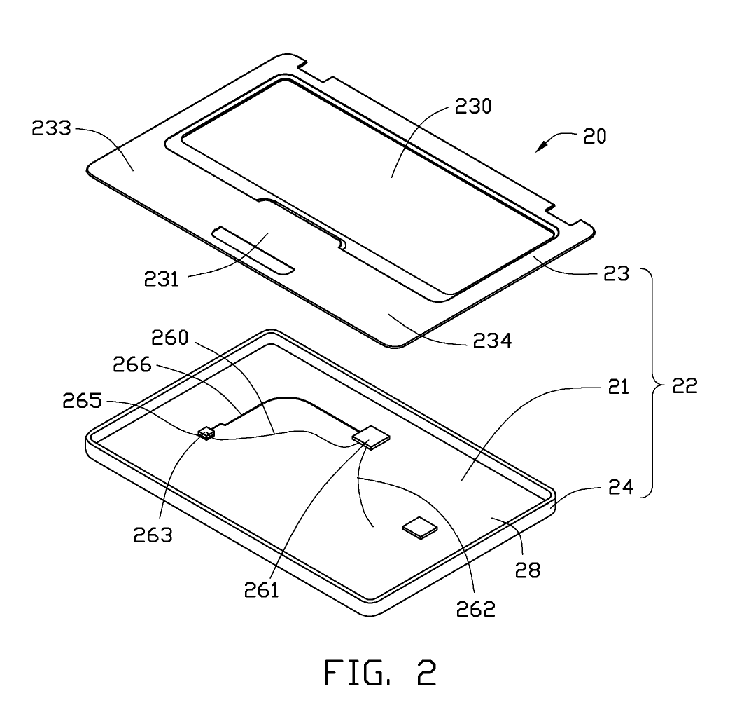

Referring also to FIG. 2, the temperature control unit 26 includes a controller 261, a heater 263, an electric wire 266 electrically connecting the heater 263 and the controller 261, a first temperature sensing wire 260 and a second temperature sensing wire 262.

The heater 263 is located under the left palm rest 263. A top surface of the heater 263 contacts a bottom surface of the left palm rest 263. The heater 263 is a resistance-type heater for generating heat to the left palm rest 263 by an electric current supplied thereto. A heat insulating layer 265 is covered at a bottom surface of the heater 263. The insulating layer 265 can avoid rising in temperature in the vicinity of the heater 263, thereby avoiding excessive heat generated by the heater 263 from being dissipated into an interior of the host computer 20 to cause negative effect. Alternatively, the heater 263 can be a thermoelectric heating chip or any one of the many standard heaters known in the art.

The controller 261 includes a processor having a temperature control program set therein. One end of the first temperature sensing wire 260 connects to the controller 261, and the other end of the first temperature sensing wire 260 is affixed to the top surface of the heater 263. When assembled, since the top surface of the heater 263 contacts the bottom surface of the left palm rest 233, the other end of the first temperature sensing wire 260 is sandwiched between the top surface of the heater 263 and the bottom surface of the left palm rest 233. Alternatively, the heater 263 can be located under the left palm rest 233 having a distance defined between the top surface of the heater 263 and the bottom surface of the left palm rest 233, and the other end of the first temperature sensing wire 260 is directly affixed to the bottom surface of the left palm rest 233. One end of the second temperature sensing wire 262 connects to the controller 261, and the other end of the second temperature sensing wire 262 is affixed to a bottom surface of the right palm rest 234. The first and second temperature sensing wires 260, 262 are configured to detect a plurality of surface temperatures of the left and right palm rests 233, 234, respectively.

During operation, the controller 261 firstly reads the surface temperatures of the left and right palm rests 233, 234 via the first and second temperature sensing wires 260, 262, respectively, then compares the surface temperature of the left palm rest 233 with the surface temperature of the right palm rest 234, and finally outputs a control signal to the heater 263 according to the compared result. Due to the presence of the electronic component 25 adjacent to the right palm rest 234, the surface temperature of the right palm rest 234 is generally much higher than the surface temperature of the left palm rest 233. When the surface temperature of the right palm rest 234 becomes larger than the surface temperature of the left palm rest 233 over a predetermined range, the controller 261 outputs the control signal to the heater 263 and supply an electric current corresponding to the control signal to the heater 263 via the electric wire 266. Thus, the heater 263 generates heat to thereby increase the surface temperature of the left palm rest 233. Thus, the temperature control unit 26 can reduce a temperature difference between the left and right palm rests 233, 234. In this embodiment, the predetermined range is 5 degrees Celsius.

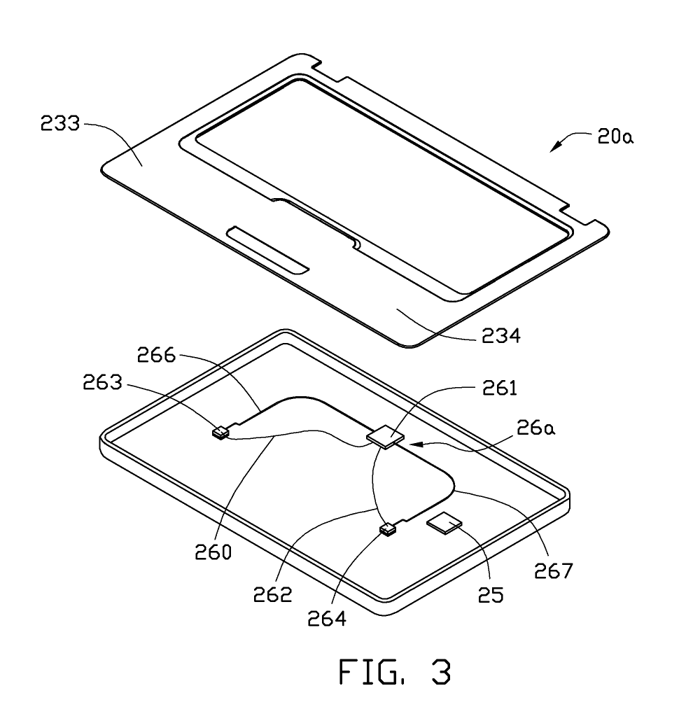

FIG. 3 shows a second embodiment of a host computer 20a of the portable computer 100. The host computer 20a differs from the host computer 20 of the first embodiment only in that a temperature control unit 26a of the host computer 20a further includes another heater 264 located under the right palm rest 234 and another electric wire 267 electrically connects the heater 264 with the controller 261. The another heater 264 has the same configuration and function as those of the heater 263 in the first embodiment.

In this embodiment, during operation, the controller 261 reads the surface temperatures of the left and right palm rests 233, 234 via the first and second temperature sensing wires 260, 262, respectively, compares the surface temperature of the left palm rest 233 and the surface temperature of the right palm rest 234 with respect to a predetermined value, respectively, and outputs a first control signal to the heater 263 and a second control signal to the another heater 264 according to the compared results.

Due to the presence of the electronic component 25 adjacent to the right palm rest 234, the surface temperature of the right palm rest 234 is generally much higher than the surface temperature of the left palm rest 233. When the surface temperature of the left palm rest 233 is less than the predetermined value over a predetermined range, the controller 261 outputs the first control signal to the heater 261 and supplies a first electric current corresponding to the first control signal to the heater 263. The heater 263 thereby generates a specific quantity of heat to increase the surface temperature of the left palm rest 233.

Alternatively, when the surface temperature of the right palm rest 234 is less than the predetermined value over the predetermined range, the controller 261 outputs the second control signal to the another heater 264 and supplies a second electric current corresponding to the second control signal to the another heater 264, thereby increasing the surface temperature of the right palm rest 234. Since the controller 261 can output the separate first and second control signals to control the two heaters 263, 264 independently, the temperature unit 26a can maintain the outer surfaces of the first and second palm rests 233, 234 both to a specified temperature, to thus reduce a temperature difference between the first and second palm rests 233, 234. Furthermore, when the portable computer 100 is used during cold weather conditions, the hands of the user contacting the left and right palm rests 233, 234 will not be hurt by excessively cold surface temperatures. In this embodiment, the predetermined value is 25 degrees Celsius.

It is to be understood, however, that even though numerous characteristics and advantages of the disclosure have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A portable computer, comprising:
a casing, the casing comprising a first outer portion having a first surface temperature and a second outer portion having a second surface temperature; and
a temperature control unit received in the casing, the temperature control unit comprising a controller, two temperature sensing wires and a heater, the heater located at the first outer portion and coupled to the controller, the temperature sensing wires each comprising a first end and a second end, the first ends being coupled to the controller, and the second ends respectively attaching the first and second outer portions for detecting the first and second surface temperatures thereof;
wherein during operation, the controller reads the first and second surface temperatures of the first and second outer portions via the temperature sensing wires, respectively, and outputs a control signal to the heater, thereby controlling operation of the heater to reduce a temperature difference between the first and second outer portions.

2. The portable computer of claim 1, wherein the controller compares the first surface temperature with the second surface temperature, and outputs the control signal to the heater according to the compared result.

3. The portable computer of claim 1, wherein the temperature control unit further comprises another heater located at the second outer portion of the casing, the controller comparing the first surface temperature and the second surface temperature with respect to a predetermined value, respectively, and outputting the control signal to the heater and another control signal to the another heater according to the compared results, respectively.

4. The portable computer of claim 3, wherein the predetermined value is 25 degrees Celsius.

5. The portable computer of claim 1, wherein the casing comprises a host computer and a display pivotally connected to one side of the host computer, the host computer comprising a touch screen at a top surface thereof, and left and right palm rests arranged at two opposite sides of the touch screen, respectively, and the left and right palm rests functioning as the first and second outer portions of the casing, respectively.

6. The portable computer of claim 5, wherein one surface of the heater contacts the left palm rest, and a heat insulating layer covers on another surface of the heater.

7. The portable computer of claim 5, wherein one of the temperature sensing wires is connected between the controller and the left palm rest, and the other temperature sensing wire is connected between the controller and the right palm rest.

8. A portable computer, comprising:
a casing, the casing comprising two surface areas having a plurality of surface temperatures;
a temperature control unit received in the casing, the temperature control unit comprising a controller, two temperature sensing wires and a heater; the temperature sensing wires each comprising a first end and a second end, the first ends being coupled to the controller, and the second ends respectively attaching the two surface areas for detecting the surface temperatures thereof; during operation, the controller reading the surface temperatures of the two surface areas via the two temperature sensing wires, respectively, and outputting a control signal to the heater to control the heater heating one of the two surface areas which has the lower surface temperature, to reduce a temperature difference between the two surface areas.

9. The portable computer of claim 8, wherein the casing comprises a host computer and a display pivotally connected to one side of the host computer, the host computer comprising a touch screen at a top surface thereof, and left and right palm rests arranged at two opposite sides of the touch screen, respectively, and the left and right palm rests functioning as the two surface areas, respectively.

10. The portable computer of claim 9, wherein the controller compares the first surface temperature with the second surface temperature, and outputs the control signal to the heater according to the compared result.

11. The portable computer of claim 9, wherein the temperature control unit further comprises another heater, the two heaters located under the left and right palm rests, respectively; the controller comparing the first surface temperature and the second surface temperature with a predetermined value, respectively, and outputting the control signal to the heater and another control signal to the another heater according to the compared results, respectively.

12. The portable computer of claim 11, wherein the predetermined value is 25 degrees Celsius.

13. The portable computer of claim 11, wherein the top surfaces of the heaters contact the bottom surfaces of the left and right palm rests, respectively, and a heat insulating layer is covered on the bottom surface of each of the heaters.
